(19) United States
(12) Patent Application Publication
(10) Pub. No.: US 2011/0116246 A1
(43) Pub. Date: May 19, 2011

(54) PRINTED CIRCUIT BOARD HAVING ELECTRO-COMPONENT AND MANUFACTURING METHOD THEREOF

(75) Inventors: Jin-Won LEE, Seoul (KR); Yul-Kyo Chung, Yongin-si (KR); Seung-Hyun Sohn, Suwon-si (KR); Moon-Il Kim, Yoosung-gu (KR)

(73) Assignee: SAMSUNG ELECTRO-MECHANICS CO., LTD.

(21) Appl. No.: 12/818,497

(22) Filed: Jun. 18, 2010

(30) Foreign Application Priority Data
Nov. 17, 2009 (KR) 10-2009-0110960

(51) Int. Cl. H05K 1/18; B32B 37/02

(52) U.S. Cl. 361/761; 156/60

(57) ABSTRACT

An electronic component embedded printed circuit board and a method of manufacturing the same are disclosed. The electronic component embedded printed circuit board in accordance with an embodiment of the present invention can include a first substrate, which has a cavity formed therein, a first electronic component, which is embedded in the cavity in a face-down manner, a second electronic component, which is stacked on an upper side of the first electronic component and embedded in the cavity in a face-up manner, and a second substrate, which is stacked on upper and lower surfaces of the first substrate.

### CROSS-REFERENCE TO RELATED APPLICATIONS

This application claims the benefit of Korean Patent Application No. 10-2009-0110960, filed with the Korean Intellectual Property Office on Nov. 17, 2009, the disclosure of which is incorporated herein by reference in its entirety.

### BACKGROUND

1. Technical Field

The present invention is related to an electronic component embedded printed circuit board and a manufacturing method of the printed circuit board.

2. Description of the Related Art

With the development of the electronic industry, there is a growing demand for smaller and higher functional electronic components. Particularly, the market trend based on lighter, thinner, shorter and smaller personal mobile devices has resulted in increasingly thinner printed circuit boards.

Emerging as a result are ways of mounting the components that are different from the conventional component mounting methods. One such example is an embedded printed circuit board, in which an active device, such as an IC, or a passive device, such as an MLCC-type capacitor, is mounted inside a printed circuit board, resulting in a higher density and improved reliability of the devices or improved performance of the package itself through an organic combination.

In the embedded printed circuit board, an opening (cavity), into which an electronic component is inserted, is formed in a pre-manufactured core substrate, and then the electronic component is embedded at a corresponding location. Then, embedded parts are fixed by filling an insulation material between the embedded parts and the core substrate.

### SUMMARY

The present invention provides an electronic component embedded printed circuit board and a manufacturing method of the printed circuit board that can implement a lighter, thinner, shorter and smaller final product by maximizing the reduction in the size of the printed circuit board and maximizing the utilization of the area of the printed circuit board.

An aspect of the present invention provides an electronic component embedded printed circuit board. The electronic component embedded printed circuit board in accordance with an embodiment of the present invention can include a first substrate, which has a cavity formed therein, a first electronic component, which is embedded in the cavity in a face-down manner, a second electronic component, which is stacked on an upper side of the first electronic component and embedded in the cavity in a face-up manner, and a second substrate, which is stacked on upper and lower surfaces of the first substrate.

The first electronic component and the second electronic component can be different in size.

A via for interlayer connection can be formed on the second substrate, and the via can be in direct contact with an electrode of the first electronic component or an electrode of the second electronic component.

Another aspect of the present invention provides a method of manufacturing an electronic component embedded printed circuit board. The method in accordance with an embodiment of the present invention can include perforating a cavity in a first substrate, adhering an adhesive tape to a lower surface of the first substrate, embedding a first electronic component in the cavity in a face-down manner such that the first electronic component is seated on the adhesive tape, stacking a second electronic component on an upper side of the first electronic component such that the second electronic component is embedded in the cavity in a face-up manner and stacking a second substrate on upper and lower surfaces of the first substrate.

The first electronic component and the second electronic component can be different in size.

The method can further include forming a via for interlayer connection in the second substrate, and the via can be in direct contact with an electrode of the first electronic component or an electrode of the second electronic component.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of an electronic component embedded printed circuit board in accordance with an embodiment of the present invention.

FIG. 2 is a flow diagram illustrating a method of manufacturing an electronic component embedded printed circuit board in accordance with an embodiment of the present invention.

FIGS. 3 to 9 are diagrams illustrating each process of manufacturing an electronic component embedded printed circuit board in accordance with an embodiment of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed descriptions of related art are omitted when it is deemed that they may unnecessarily obscure the essence of the invention.

While such terms as “first,” “second,” etc. may be used to describe various components, such components must not be limited to the above terms. The above terms are used only to distinguish one component from another.

An electronic component embedded printed circuit board and a method of manufacturing the printed circuit board in accordance with certain embodiments of the present invention will be described below in more detail with reference to the accompanying drawings. Those components that are the same or are in correspondence are rendered the same reference numeral regardless of the figure number, and redundant descriptions are omitted.

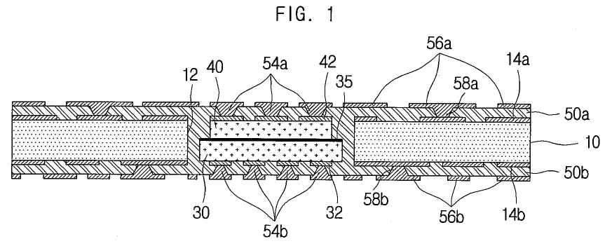

FIG. 1 is a cross-sectional view of an electronic component embedded printed circuit board in accordance with an embodiment of the present invention. As illustrated in FIG. 1, the printed circuit board of the present embodiment includes a first substrate 10, which has a cavity 12 formed therein, a first electronic component 30, which is embedded in the cavity 12 in a face-down manner, a second electronic component 40, which is stacked on an upper side of the first electronic component 30 and embedded in the cavity 12 in a face-up manner, and second substrates 50a and 50b, which are stacked on upper and lower surfaces, respectively, of the first substrate 10.

The first substrate 10 having the cavity 12 formed therein can be a core substrate. That is, the first substrate 10 can have a structure in which a reinforcing material, such as glass fiber or carbon fiber, is impregnated in an insulation resin. If a core substrate having a reinforcing material, which reinforces the rigidity, impregnated therein is used, warpage of the first substrate 10 can be reduced, thus improving the product reliability. This, however, is by no means to restrict the present invention to this embodiment, and it shall be apparent that various other materials, for example, a metal core, can be used for the first substrate 10.

The cavity 12, which is provided in the first substrate 10 in order to embed the electronic components 30 and 40, can be formed by drilling the first substrate 10. The electronic components 30 and 40 are vertically stacked and embedded in the cavity 12. That is, as illustrated in FIG. 1, the first electronic component 30 and the second electronic component 40, which is stacked on the first electronic component 30, are embedded in the cavity 12. Since a plurality of electronic components 30 and 40 are vertically stacked and embedded in a single cavity 12, the reduction in the size of the printed circuit board can be maximized.

Here, the first electronic component 30, which is located relatively lower than the second electronic component 40, is embedded by a face-down method, and the second electronic component 40, which is located relatively higher than the first electronic component 30, is embedded by a face-up method. Through this structure, a circuit can be designed in such a way that the first electronic component 30 directly transmits a signal in a downward direction of the first substrate 10 and the second electronic component 40 directly transmits a signal in an upward direction of the first substrate 10. Accordingly, the upward and downward directions of the first substrate 10 can be efficiently utilized, and signals can be transmitted using minimum paths. Therefore, the area of the printed circuit board can be maximally utilized, making it easier to implement a lighter, thinner, shorter and smaller final product.

The second substrates 50a and 50b are stacked on upper and lower surfaces, respectively, of the first substrate 10 to cover the first electronic component 30 and the second electronic component 40, respectively. Wiring patterns 56a and 56b for signal transmission and vias 54a and 54b for interlayer connection are provided in the second substrates 50a and 50b. Here, the vias 54a and 54b can be in direct contact with an electrode 32 of the first electronic component 30 or an electrode 42 of the second electronic component 40. Specifically, the via 54a on the second substrate 50a that is stacked on the upper side of the first substrate 10 can be in direct contact with the electrode 42 of the second electronic component 40, which is embedded by a face-up method, and the via 54b on the second substrate 50b that is stacked on the lower side of the first substrate 10 can be in direct contact with the electrode 32 of the first electronic component 30, which is embedded by a face-down method. Accordingly, by allowing the vias 54a and 54b to be in direct contact with the electrodes 42 and 32, respectively, there requires no additional process for redistribution patterning, and signals can be transmitted using minimum paths. This is advantageous for improving the performance of the product.

Furthermore, it is also possible that additional vias 58a and 58b are used to implement interlayer connection between circuits 14a and 14b that are provided on the first substrate 10 and the circuits 56a and 56b that are provided on the second substrates 50a and 50b.

Meanwhile, as illustrated in FIG. 1, the size of the first electronic component 30 can be different from that of the second electronic component 40 in the printed circuit board of the present embodiment. In the present embodiment, the first electronic component 30 and the second electronic component 40 are vertically stacked on each other, and the first electronic component 30 is embedded by a face-down method while the second electronic component 40 is embedded by a face-up method. Accordingly, there is little chance of interruption in electrical connection between the first electronic component 30 and the second electronic component 40. As a result, the first electronic component 30 and the second electronic component 40 do not need to be the same in type or size, and thus different types or sizes of electronic components can be used. Accordingly, not only can the functions of the electronic component embedded printed circuit board be more various, but also the design freedom can be improved. Nevertheless, it is also possible that the first electronic component 30 and the second electronic component 40 can have the same type and size, as necessary.

Hitherto, the structure of an electronic component embedded printed circuit board in accordance with an embodiment of the present invention has been described. Hereinafter, a method of manufacturing the electronic component embedded printed circuit board will be described below. However, any redundant description of the electronic component embedded printed circuit board shown in FIG. 1 will be omitted.

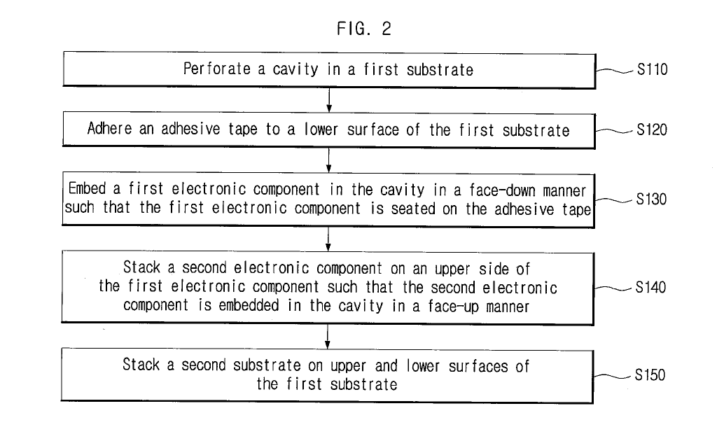

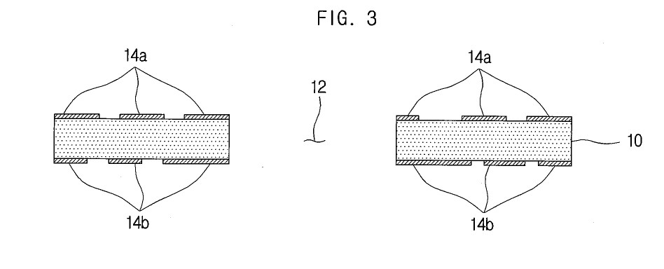

FIG. 2 is a flow diagram illustrating a method of manufacturing an electronic component embedded printed circuit board in accordance with an embodiment of the present invention, and FIGS. 3 to 9 are diagrams illustrating each process of manufacturing an electronic component embedded printed circuit board in accordance with an embodiment of the present invention.

First, as illustrated in FIG. 3, a cavity 12 is perforated in a first substrate 10 (S110). The cavity 12, which is provided in the first substrate 10 in order to embed electronic components 30 and 40, can be formed by drilling the first substrate 10.

Meanwhile, as described above, the first substrate 10 having the cavity 12 formed therein can be a core substrate or a metal core in which a reinforcing material, such as glass fiber or carbon fiber, is impregnated in an insulation resin.

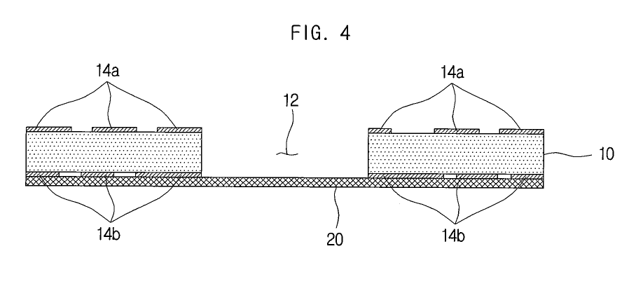

Next, as illustrated in FIG. 4, an adhesive tape 20 is adhered to a lower surface of the first substrate 10 (S120). By adhering the adhesive tape 20 to the lower surface of the first substrate 10, a lower side of the cavity 12 is closed by the adhesive tape 20.

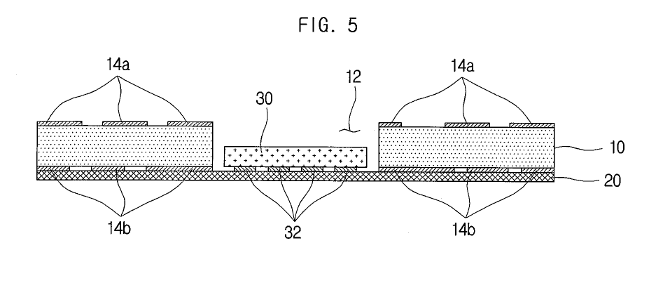

Next, as illustrated in FIG. 5, the electronic component 30 is embedded in the cavity 12 in a face-down manner (S130). That is, the first electronic component 30 is embedded in such a way that an electrode 32 faces downward. Therefore, a surface of the first electronic component 30 that has the electrode 32 formed thereon is seated on and fixed to the adhesive tape 20.

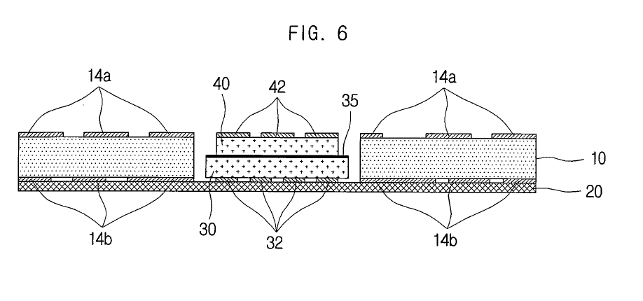

Next, as illustrated in FIG. 6, the second electronic component 40 is stacked on an upper side of the first electronic component 30 (S140). Here, the second electronic component 40 is embedded in the cavity 12 in a face-up manner. That is, the second electronic component 40 is embedded in such a way that an electrode 42 faces upward. Connection between the first electronic component 30 and the second electronic component 40 can be maintained by interposing an adhesive 35 between the first electronic component 30 and the second electronic component 40. Here, the adhesive 35 can be a die attach film (DAF), which is coated on a rear surface of a wafer during a semiconductor process of manufacturing an electronic component. In this way, no additional process for coating an adhesive may be required while the second electronic component 40 is stacked on the upper side of the first electronic component 30. Here, the adhesive 35 can be formed on any one of the first electronic component 30 and the second electronic component 40, or can be formed on both of them.

Meanwhile, as described above, the sizes of the first electronic component 30 and the second electronic component 40 can be different from each other.

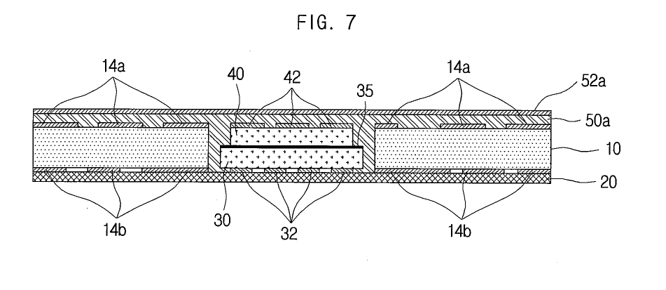

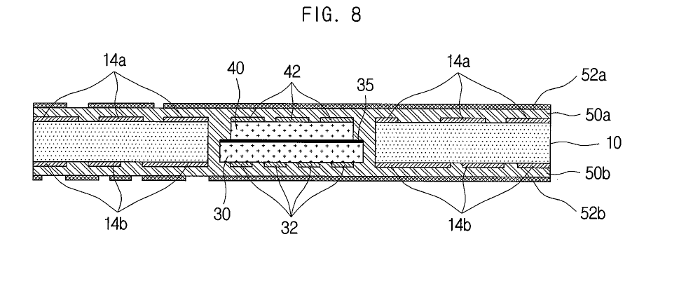

Next, the second substrates 50a and 50b are stacked on upper and lower surfaces, respectively, of the first substrate 10 (S150). For this, a first stacking process can be performed on the upper side of the first substrate 10, as illustrated in FIG. 7. Then, after the adhesive tape 20 adhered to the lower surface of the first substrate 10 is removed, a second stacking process can be performed on the lower side of the first substrate 10, as illustrated in FIG. 8.

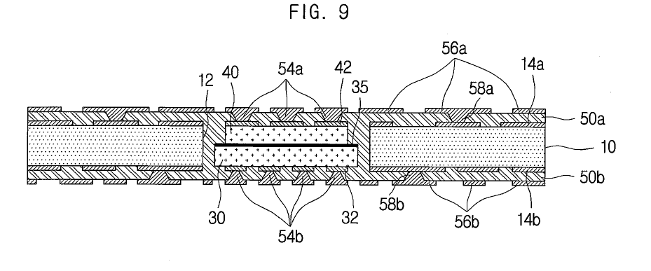

Next, as illustrated in FIG. 9, circuits 56a and 56b are patterned on the surfaces of the second substrates 50a and 50b, and vias 54a and 54b are formed for interlayer connection. Here, the vias 54a and 54b can be in direct contact with the electrode 32 of the first electronic component 30 or the electrode 42 of the second electronic component 40. Specifically, the via 54a on the second substrate 50a that is stacked on the upper side of the first substrate 10 can be in direct contact with the electrode 42 of the second electronic component 40, which is embedded by a face-up method, and the via 54b on the second substrate 50b that is stacked on the lower side of the first substrate 10 can be in direct contact with the electrode 32 of the first electronic component 30, which is embedded by a face-down method. Accordingly, by allowing the vias 54a and 54b to be in direct contact with the electrodes 42 and 32, respectively, there requires no additional process for redistribution patterning, and signals can be transmitted using minimum paths. This is advantageous for improving the performance of the product.

Furthermore, it is also possible that additional vias 58a and 58b can be used to implement interlayer connection between circuits 14a and 14b that are provided on the first substrate 10 and the circuits 56a and 56b that are provided on the second substrates 50a and 50b.

While the spirit of the invention has been described in detail with reference to certain embodiments, the embodiments are for illustrative purposes only and shall not limit the invention. It is to be appreciated that those skilled in the art can change or modify the embodiments without departing from the scope and spirit of the invention.

As such, many embodiments other than those set forth above can be found in the appended claims.

What is claimed is:

1. An electronic component embedded printed circuit board comprising:
a first substrate having a cavity formed therein;
a first electronic component embedded in the cavity in a face-down manner;
a second electronic component stacked on an upper side of the first electronic component and embedded in the cavity in a face-up manner; and
a second substrate stacked on upper and lower surfaces of the first substrate.

2. The electronic component embedded printed circuit board of claim 1, wherein the first electronic component and the second electronic component are different in size.

3. The electronic component embedded printed circuit board of claim 1, wherein:
a via for interlayer connection is formed on the second substrate; and
the via is in direct contact with an electrode of the first electronic component or an electrode of the second electronic component.

4. A method of manufacturing an electronic component embedded printed circuit board, the method comprising:
perforating a cavity in a first substrate;
adhering an adhesive tape to a lower surface of the first substrate;
embedding a first electronic component in the cavity in a face-down manner such that the first electronic component is seated on the adhesive tape;
stacking a second electronic component on an upper side of the first electronic component such that the second electronic component is embedded in the cavity in a face-up manner; and
stacking a second substrate on upper and lower surfaces of the first substrate.

5. The method of claim 4, wherein the first electronic component and the second electronic component are different in size.

6. The method of claim 4, further comprising forming a via for interlayer connection in the second substrate,
wherein the via is in direct contact with an electrode of the first electronic component or an electrode of the second electronic component.
